(19) United States
(12) Patent Application Publication
(10) Pub. No.: US 2008/0001237 A1
(43) Pub. Date: Jan. 3, 2008

(54) Semiconductor device having nitrided high-k gate dielectric and metal gate electrode and methods of forming same

(75) Inventors: Vincent S. Chang, Hsinchu (TW); Peng-Fu Hsu, Hsinchu (TW); Fong-Yu Yen, Taoyuan County (TW); Yong-Tian Hou, Singapore (SG); Jin Ying, Singapore (SG); Hun-Jan Tao, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/478,476

(22) Filed: Jun. 29, 2006

(51) Int. Cl. H01L 29/78

(52) U.S. Cl. 257/411; 257/412

(57) ABSTRACT

Disclosed is a semiconductor device having a substrate, an interfacial layer formed on said substrate, a nitrogen-containing high dielectric constant (high-k) layer formed on said interfacial layer, and a metal electrode on said nitrogen-containing high-k layer. Also disclosed is a method of forming a transistor including forming on a substrate an interfacial layer comprising silicon and oxygen, depositing on the interfacial layer a high-k dielectric material, nitriding the high-k dielectric material, depositing a metal layer on the high-k dielectric material, and patterning the metal layer, the high-k dielectric material, and the interfacial layer to form a gate stack.

### CROSS REFERENCE TO RELATED APPLICATION

This application is related to commonly owned and co-pending patent application Ser. No. 11/115,932, filed Apr., 27, 2005, and entitled Nitrogen Treatment to Improve High-K Gate Dielectrics, which application is incorporated herein by reference.

### TECHNICAL FIELD

This invention relates generally to semiconductor device structures and fabrication methods and more particularly to a device having a nitrided high-k gate dielectric and a metal gate electrode.

### BACKGROUND

A significant metric of semiconductor device performance is the off state current (I_{doff}). Power consumption, stand-by current, heat generation, and numerous other circuit characteristics are related to off state current. Off state current can be decreased by increasing the threshold voltage (Vₜ) of the device, which in turn reduces the subthreshold current (I_{soff}) component of off state current. Conventionally, threshold voltage has been increased by increasing the doping concentration in the channel region of the device, as well as the doping concentration of the pocket implants. While this scheme has been acceptable for conventional devices, the approach is insufficient as device geometries scale deeper into the sub-micron range.

In the 45 nm range, the phenomenon of diode leakage current (I_{boff}) arising from the increased channel and pocket implant doping concentrations begins to dominate, negating any benefit in reduced subthreshold current. Research shows that at the 45 nm node, off state current reaches saturation or even increases with increasing threshold voltage, as a result of the subthreshold current phenomenon.

High dielectric constant, or high-k, dielectrics have been proposed to ameliorate the effects of shrinking device geometries on leakage current. High-k dielectrics suffer from certain manufacturing and processing shortcomings, however. Most notably, due to the crystalline nature of typical high-k dielectrics, cross-wafer uniformity in the layer characteristics is quite difficult to achieve. This means that device performance variation may vary unacceptably across the wafer.

Metal gate electrodes have also been considered for ameliorating, at least in part, some of the negative effects of scaling into deep sub-micron geometries. This is due to the significant advantage of reduced depletion region that metal gates provide over convention polysilicon gates. Metal gate electrode, however, also introduces manufacturability concerns, including the difficulty of accurately and repeatedly patterning metal layers in the deep sub-micron realm. Particularly, it is difficult to pattern the relatively thick metal gate layer without over-etching into and through the relatively thin underlying gate dielectric layer—most typically silicon oxy nitride (SiON). This over-etching through the gate dielectric damages the silicon substrate surface, which negatively impacts device performance.

What is needed, then, is a novel gate stack that addresses the concerns in the art, while overcoming the shortcomings of prior approaches.

### SUMMARY OF THE INVENTION

In one aspect, the present invention provides for a semiconductor device comprising a substrate and an interfacial layer formed on the substrate. A nitrogen-containing high dielectric constant (high-k) layer is formed on the interfacial layer. A metal electrode is formed on said nitrogen-containing high-k layer.

In another aspect, the present invention provides for a semiconductor device having a semiconductor substrate and a transistor formed in the substrate. The transistor includes an interfacial layer formed on the semiconductor substrate and a gate dielectric formed on the interface layer. The gate dielectric comprises a nitrogen-containing material having a high dielectric constant. The transistor further includes a metal gate electrode formed on the gate dielectric and a non-nitrogen-containing layer formed on the gate dielectric. The transistor also has a first source/drain region formed in the substrate, wherein a portion of the first source/drain region underlies a first portion of the gate dielectric and gate electrode, and a second source/drain region formed in the substrate, wherein a portion of the second source/drain region underlies a second portion of the gate dielectric and gate electrode.

In yet another aspect, the present invention provides for an integrated circuit. The integrated circuit includes a silicon substrate and a transistor formed at least partially on the substrate. The transistor includes a source region, a drain region, and a channel region defined between the source region and the drain region, the channel region having a nominal length of about or less than 45 nm. The transistor also includes an interfacial layer overlying the channel region and a gate dielectric overlying the interfacial layer. The gate dielectric contains nitrogen with a nitrogen atomic ratio of from about five percent to about thirty percent. A metal gate electrode overlies the gate dielectric. The integrated circuit also includes an etch stop layer overlying the transistor and having first contact openings formed therein, at least one contact opening substantially aligned with the gate electrode, an inter-layer dielectric over the etch stop layer and having second contact openings formed therein, at least one contact opening substantially aligned with the gate electrode, a conductive metal substantially filling the first and second contact openings, and a metal interconnect layer overlying the inter-layer dielectric and electrically contacting the conductive metal in the first and second contact openings.

In yet another aspect, the present invention provides for a method of forming a transistor. The method includes forming an interfacial layer over a substrate, and forming a nitrogen-containing high dielectric constant (high-k) layer over the interfacial layer. A metal layer is formed over the high-k layer. Finally, the metal layer and the high-k layer are patterned. The high dielectric constant layer can be deposited as a nitrogen containing layer. Alternatively, the high dielectric constant material can be nitrided after it is deposited over the interfacial layer. In some embodiments, a polysilicon layer is formed over the metal layer.

Advantageous features of the present invention include scalability to deep sub-micron geometries, including 45 nm and below. Another advantageous feature is the amorphous (non-crystalline) structure resulting from the nitrided high-k dielectric material. This results in improved uniformity of the layer's characteristics and performance across the wafer. Yet another advantageous feature is the improved leakage current characteristics of the resulting structure due to the higher dielectric properties of the high-k gate dielectric.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a and 1b illustrate in cross-section that layers form a gate stack for illustrative embodiments of the invention;

FIG. 2a is a chart illustrating, for an exemplary nano-laminated ALD process, the relationship between the ratio of HfO₂ and SiO₂ deposition cycles and the resulting atomic ratio of silicon in the resulting film;

FIG. 2b is a chart illustrating an exemplary nano-laminated ALD process, the relationship between the relative number of HfO₂ and SiO₂ deposition cycles and the dielectric constant of the resulting film;

FIG. 3 schematically illustrates a multi-chamber deposition tool that is advantageously employed in illustrative manufacturing processes of embodiments of the present invention;

FIGS. 4a through 4d illustrate in cross section the patterning of the metal stack layers to form the novel metal gate stack of respective illustrative embodiments of the present invention; and

FIGS. 5a and 5b illustrate in cross section further elements of respective integrated circuits incorporating features of respective illustrative embodiments of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

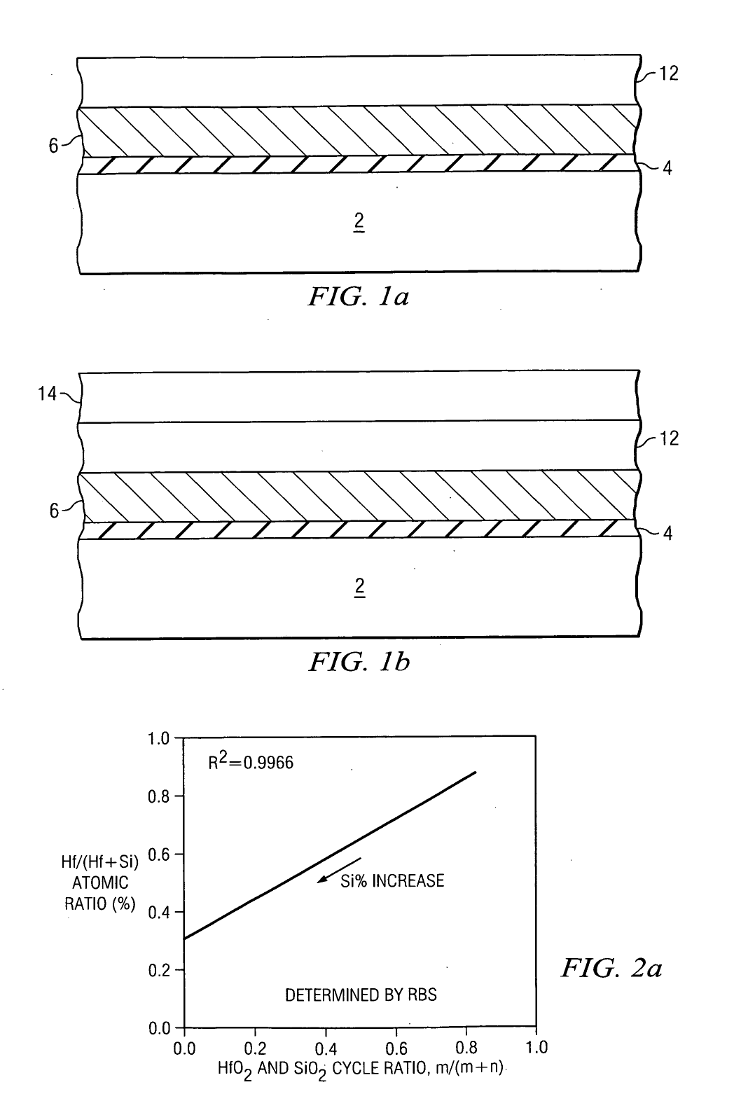

FIG. 1a illustrates in cross section an illustrative gate stack embodiment of the present invention. The gate stack is formed on a substrate 2, which may be bulk silicon, silicon on insulator (SOI), silicon on sapphire (SOS), or alternative substrates such as SiGe, Ge, or III-V materials. As will be explained below, substrate 2 preferably has formed in it doped regions and isolation regions such as are conventionally known in the art.

Interfacial layer 4 is formed on substrate 2. Interfacial layer 4 is preferably formed of silicon oxide (SiO2), although other materials could be employed, such as silicon oxynitride (SiOxNy), silicon nitride (SiNx), or oxides and/or nitrides of other materials such as aluminum (Al), hafnium (Hf), tantalum (Ta), titanium (Ti), zirconium (Zr), lanthanum (La), dysprosium (Dy), scandium (Sc), and the like.

In one illustrative embodiment, interfacial layer is a by-product of a wafer cleaning step, meaning no separate or additional process step is employed to form interfacial layer 4. In an exemplary embodiment, a standard wafer cleaning step involves a first wet bath using a solution of NH3/H2O2/H2O (so-called standard clean 1 or SC1, or ammonia peroxide mix or APM) followed by a second wet bath using a solution of HCl/H2O2/H2O (so-called standard clean 2 or SC2, or hydrochloric peroxide mix or HPM). In the exemplary embodiment, the standard wafer clean baths are at atmospheric pressure and a temperature of from about 50 C to about 60 C. The wafer cleaning step results in, not only a clean wafer surface, but also a good quality chemically grown oxide film on the exposed wafer surface(s).

In other embodiments, interfacial layer 4 is formed (at least partially) by a thermal or chemical oxidation process. In the thermal oxidation process, substrate 2 is subjected to an oxidizing environment such as steam or oxygen-containing ambient at a temperature of about 600 C to about 1100 C for a period of about 5 seconds to about 1800 seconds. Alternatively, interfacial layer can be formed by exposing wafers in ozone-containing water or by convention chemical vapor deposition (CVD) using chemicals such as TEOS or SiH4+N2O.

In the illustrative embodiments, interfacial layer 4 is formed to a thickness of from about less than 1 nm to about 3 nm and preferably to about 1 nm. Theoretically, the interfacial layer could be eliminated entirely. This is undesirable, however, because subsequently formed high-k dielectric material 6 typically has a high defect density, relative to oxide. These defects create charge trapping sites that impede charge carrier mobility. Hence, it is preferable to include interfacial layer 4 so as to separate high-k layer 6 from the channel region formed in substrate 2.

A high dielectric constant, or high-k, layer 6 is formed atop interfacial layer 4. In an illustrative embodiment, high-k layer 6 is deposited by nano-laminated atomic layer deposition (ALD). In illustrative embodiments, high-k layer 6 is formed to a thickness of from about 1 nm to about 10 nm. In the case of HfSiO, during the nano-laminated ALD process, the Hf and Si precursors are alternatingly injected into the reaction chamber, forming HfO₂ and SiO₂, respectively. One complete HfSiO ALD cycle consists of m ALD cycles of HfO₂ and n ALD cycles of SiO₂. Such HfSiO ALD cycles are repeated until a desired HfSiO thickness is obtained. Preferably, the number of HfSiO ALD cycle ranges from 5 to 80. The precursors of HfO2 include inorganic chemicals such as HfCl4 or organic chemicals such as tetrakis (ethylmethylamino) hafnium (TEMAH). The deposition temperature ranges from 300 to 400° C.

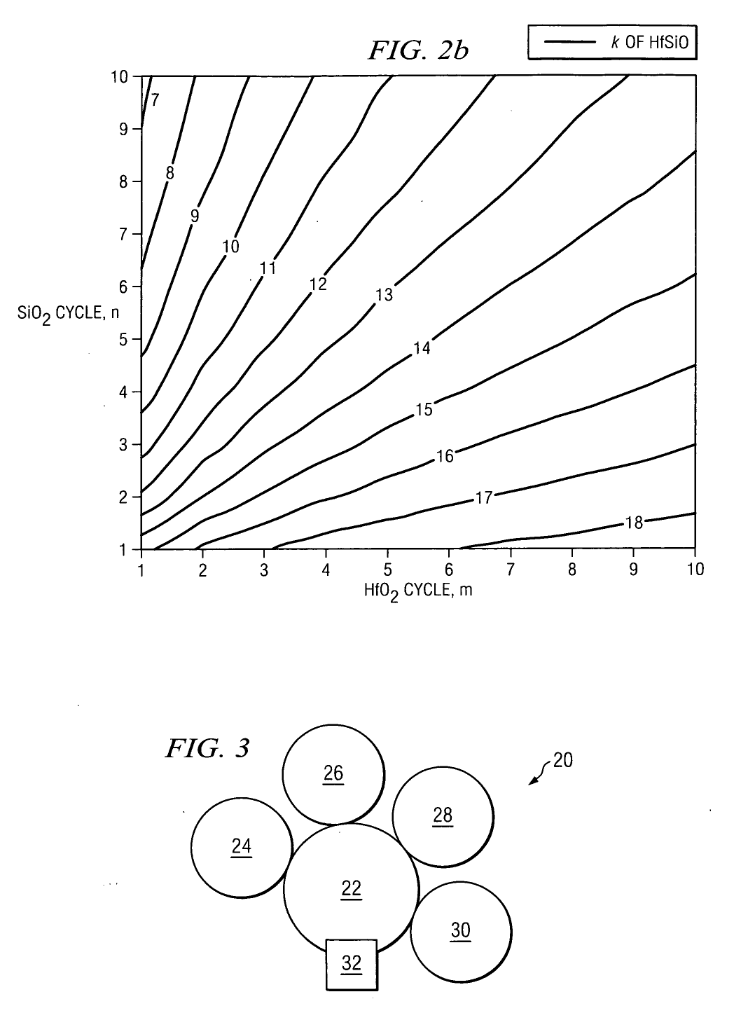

In illustrative embodiments, high-k layer 6 comprises hafnium silicon oxide (HfSiO). An advantageous feature of the nano-laminated ALD deposition process is the ability to control the silicon content of the resulting dielectric material and to also control the dielectric constant, or k value, of the layer. FIG. 2a illustrates the relationship between the hafnium atomic ratio (and inversely the silicon atomic ratio) of the resulting layer 6 as a function of the cycle ratio between HfO2 and SiO2. As expected, as the ratio of HfO2 deposition cycles (relative to the total number of HfO2 and SiO2 cycles) increases, the atomic ratio of Hf increases—meaning the atomic ratio of Si is decreasing. Moving to the left of the graph, the ratio of HfO2 decreases, resulting in less Hf and a greater atomic ratio of silicon in the resulting film. Adjusting the silicon ratio impacts the work function of the film which, as is well known, affects the threshold voltage of the resulting device. In illustrative embodiments, the silicon atomic ratio ranges from about zero percent silicon to about ninety percent silicon. Preferably, the silicon atomic ratio ranges from about 20 percent to about 60 percent.

FIG. 2b illustrates the impact on the dielectric constant of the material resulting from the relationship between the relative number of HfO2 deposition cycles (m) and SiO2 deposition cycles (n). As shown, the dielectric constant of the film is impacted by both the total number of HfO2 and SiO2 deposition cycles, and also by the relative number of HfO2 deposition cycles versus SiO2 deposition cycles. As an example, if a total of twelve cycles are employed with an equal number of HfO2 deposition cycles and SiO2 deposition cycles, the resulting film dielectric constant is approximately 13.5, as illustrated at point 8 of the graph. On the other hand, the dielectric constant is slightly less than 16 when eight HfO2 deposition cycles and four SiO2 deposition cycles are employed, even though the total number of cycles remains at twelve. This is illustrated at point 10 of the graph.

As deposited, HfSiO is amorphous in structure, but become poly-crystalline after a high-temperature S/D activation anneal. This is disadvantageous because it is difficult to control the uniformity of the poly-crystalline film across the wafer surface. Because the grain size, grain boundaries, and grain orientations may vary widely and randomly across the wafer, threshold voltage will also vary across the wafer. The phenomenon is particularly pronounced as device geometries shrink. For device geometries with a relatively short channel length, the variation in threshold voltage can be quite pronounced across a wafer. In the illustrative embodiments, a nitridation step is performed on high-k dielectric layer 6, which maintains the film in an amorphous state after a subsequent high-temperature S/D activation anneal. As a result, threshold voltage uniformity increases.

In one illustrative embodiment, high-k layer 6 is nitrided by thermal nitridation. One example is exposing the film to an ammonia-containing environment at 600-900° C. and 500-8000 Pa for a period of about 60-300 seconds. Other process parameters may be employed, as will be obvious to one skilled in the art.

In another illustrative embodiment, high-k layer 6 is nitrided by a plasma process. One example is exposing the film to a nitrogen-containing plasma environment at 20-100° C. and 1-10 Pa and an exciting frequency of about 13.56 MHz and 100-1000 W for about 30-300 seconds.

In exemplary embodiments, the resulting nitrided high-k layer 6 has a nitrogen atomic ratio of from about five percent to about thirty percent, and more preferably of about 15 percent to about 25 percent.

In the described embodiments, high-k layer 6 comprises HfSiO (prior to being nitrided). In other embodiments, other materials may be used, such as metal oxides and/or metal silicates of e.g., hafnium, aluminum, zirconium, lanthanum, tantalum, titanium, and combinations of these materials. In preferred embodiments, HfO2 and more preferably HfSiO is employed.

In the above described embodiment, the high-k dielectric layer 6 is deposited in an amorphous state (but will become poly-crystalline after a subsequent high-temperature S/D activation anneal) and is subsequently nitridated to maintain the layer in an amorphous state. In other illustrative embodiments, the high-k layer can be deposited in a nitrided state. For instance, high-k dielectric layer 6 could alternatively be deposited using metal-organic-chemical vapor deposition (MOCVD) process. As is known in the art, by selecting nitrogen-containing precursor materials, the resulting high-k film can be nitrided in situ during the deposition process. In one example, the MOCVD process that uses hafnium amides (such as tetrakis(ethylmethylamino)hafnium (TEMAH) and silicon amides (such as tetrakis(dimethylarnino) silane (TDMAS).

Returning back to FIG. 1a, a metal layer 12 is formed atop the nitrided high-k dielectric layer 6. In one illustrative embodiment, metal layer 12 comprises tantalum carbide (TaCx). Other materials could be employed, including metals (Ta, Ti, Ru, Mo, W, etc.), metal alloys, metal nitrides (TaN, TiN, Mo2N, etc.), metal carbides (TaCx, etc.), and conducting metal oxides (RuO2, MoOx, etc.) and the like. In illustrative embodiments, metal layer 12 is formed by ALD or physical vapor deposition (PVD) to a thickness ranging from about 1 nm to about 30 nm. In exemplary embodiments, metal layer 12 is formed to a thickness of about 5-15 mm.

As will be described below, the metal stack comprising interfacial layer 4, nitrided high-k dielectric layer 6, and metal layer 12 can be patterned to form metal gates for subsequently formed transistor devices. Prior to that discussion, however, an alternative embodiment is discussed with reference to FIG. 1b. FIG. 1b illustrates the same structure as shown in FIG. 1a, but with the addition of polysilicon cap layer 14 atop metal layer 12. Polysilicon cap layer 14 is preferably formed by CVD deposition, although other deposition techniques may be employed. The cap layer 14 is formed to a thickness sufficient to satisfy the particular design requirements. In illustrative embodiments, cap layer 14 is formed to a thickness of form about 30 nm to about 200 nm. In one exemplary embodiment, cap layer 14 is formed to a thickness of about 700-1200 nm.

An advantageous feature of polysilicon cap layer 14 is that it prevents cross contamination of the metal(s) employed in forming metal gate electrode layer 12 and subsequent processing tools. For instance, in the absence of polysilicon cap layer 14, TaCx could diffuse from metal layer 12 in subsequent process steps and contaminate the processing chamber of production tools used to fabricate the integrated circuit. Polysilicon cap layer 14 prevents this diffusion and hence prevents contamination. Alternatively, a dedicated processing tool could be employed for the product line, in which case cross contamination would not be an issue.

Another advantage of polysilicon cap layer 14 is that it allows minimal changes on the current fabrication process and transistor structure, which also uses polysilicon as a gate electrode. For instance, in the absence of polysilicon cap layer 14, the thickness of metal gate electrode layer 12 needs to increase substantially, resulting in the need of a new process or major process change for the subsequent gate etching step.

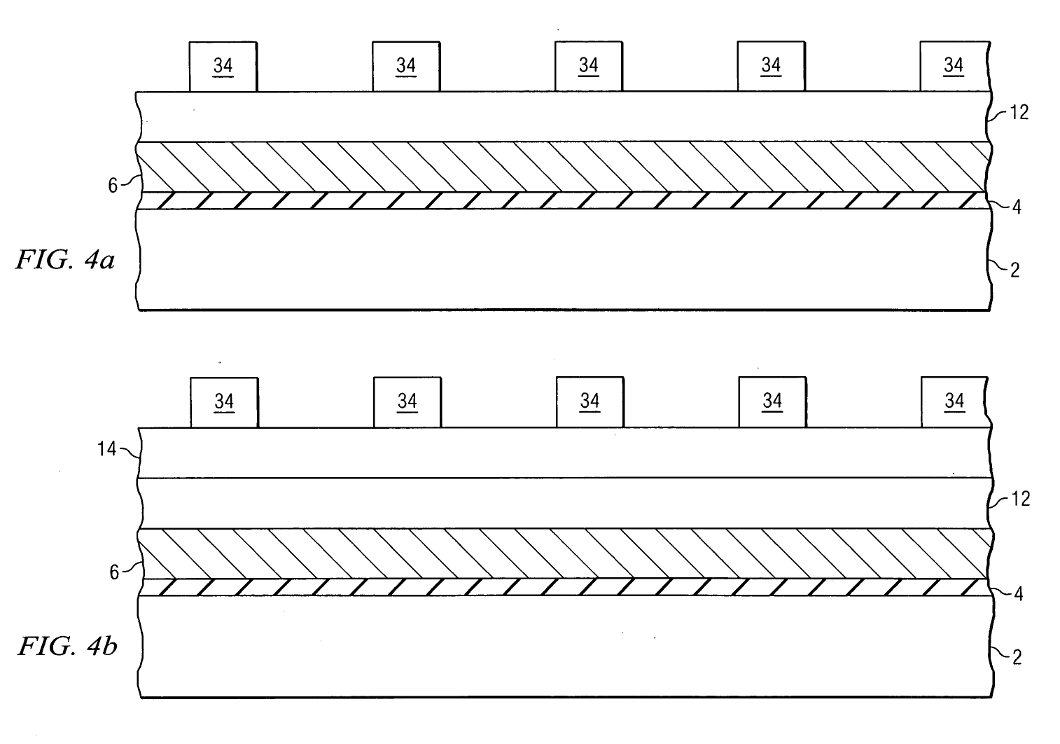

One advantageous feature of the illustrative embodiments, as illustrated in both FIG. 1a and FIG. 1b, is the ability to form or deposit the various layers in a single deposition tool. This means that, once the wafer(s) is placed in the tool, the high-k dielectric layer deposition, the high-k dielectric layer nitridation, the metal layer deposition, and the polysilicon layer (if included) deposition can all be accomplished in one processing tool, such as schematically illustrated FIG. 3. Deposition tool 20 is schematically illustrated as having a transfer chamber 22 and four processing chambers 24, 26, and 28, and 30, respectively, in what is typically referred to as a cluster tool configuration. Wafers are transferred into and out of tool 20, either individually or in batches, via loadlock mechanism 32. Once transferred into transfer chamber 22 via loadlock mechanism 32, the wafers are isolated from the ambient environment. Typically, an inert gas such as nitrogen is purged through transfer chamber 22 which is pumped down to a low pressure, if not vacuum, typically ranging from 200 to 1000 Pa, to remove any air from the atmosphere through the loadlock mechanism 32. When wafers are transferred into or out of processing chambers 24, 26, 28, and 30, processing chambers 24, 26, 28, and 30 are also pumped down to a similar pressure, which is in equilibrium with the pressure of the transfer chamber 22.

Processing may begin by one or more wafers being transferred from transfer chamber 22 into processing chamber 24 using a belt, robotic arm, or other well-known transfer mechanism (not shown). Processing chamber 24 is equipped with heating elements, gas flow orifices, radio frequency coils, and other equipment (not shown) necessary to affect the desired process. In the illustrative embodiment, high-k dielectric layer 6 is deposited in processing chamber 24. After formation of high-k dielectric layer, the wafer(s) is transferred from processing chamber 24, via transfer chamber 22, to processing chamber 26. Thermal or plasma nitridation is performed in processing chamber 26. Note that by utilizing cluster tool 20, vacuum need not be broken when transferring the wafer(s) between processing chambers. This eliminates the possibility of the reactions of the high-k dielectric layer 6, the underlying interfacial layer 4, and the underlying substrate 2 with air or the moisture in the air. This also reduces the possibility of damage to the wafer from handling and the likelihood of contamination arising from exposure to the ambient environment. After nitridation, the wafer is transferred from processing chamber 26, via transfer chamber 22, again without breaking vacuum, to processing chamber 28 where metal layer 12 is deposited, as described above. Optionally, if a polysilicon cap layer 14 is employed, the wafer(s) can be transferred to processing chamber 30 where the polysilicon cap layer 14 is deposited. In the alternate embodiment of FIG. 1b, wherein the high-k dielectric layer 6 is deposited with in-situ nitridation, the nitridation process might be skipped and the wafer(s) transferred directly from chamber 24 (high-k dielectric layer deposition) to chamber 28 (metal deposition).

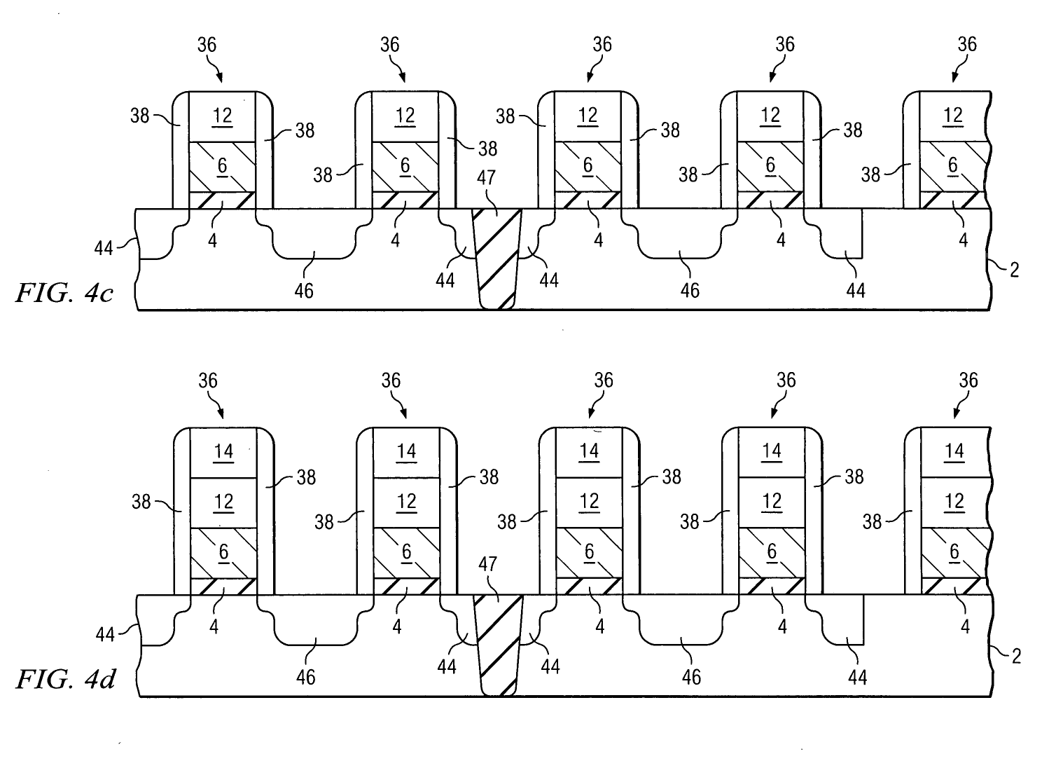

FIGS. 4a and 4b illustrate the patterning of the metal stack layers to form the novel metal gate stack of the illustrative embodiments of the present invention. As shown, a photoresist layer 34 is deposited over the metal gate stack layers and patterned using known photolithographic techniques. The patterning of photoresist layer 34 leaves the underlying layers exposed where those layers will be removed.

Using known etching techniques, polysilicon layer 14 (if there, as shown in FIG. 4b), metal layer 12, high-k dielectric layer 6, and interfacial layer 4 are respectively etched to form metal gate stacks 36 as shown in FIGS. 4c and 4d. FIG. 4c corresponds to the embodiment illustrated in FIG. 4a and FIG. 4d corresponds to the embodiment illustrated in FIG. 4b. Obviously, some features of the gate stacks are shown highly exaggerated and the features are not shown to scale. Spacers 38 may optionally be formed on the sidewalls of the respective metal gate stacks 36. In some illustrative embodiments, sidewall spacers 38 are used in processing steps and subsequently removed prior to completing manufacture of the integrated circuit. In other embodiments, sidewall spacers 38 are formed and remain on the gate stack. In yet other embodiments, no sidewall spacers are formed.

As also shown in FIGS. 4c and 4d, source/drain regions 44 and 46 are formed in substrate 2, typically by ion implantation. Alternatively, source/drain regions may be formed of a material that is epitaxially grown in trenches formed in substrate 2, which epitaxial growth includes in situ implantation of impurities to form source/drain regions 44, 46. Source/drain regions 44, 46 are substantially aligned with respective sidewalls of respective metal gate stacks 36. As is known in the art, however, portions of respective source/drain regions 44, 46 may extend partially under the respective gate stacks 36 and portions of respective source/drain regions 44, 46 may be substantially aligned with one more layers of sidewall spacers 38. One skilled in the art will recognize that a source/drain region may be shared by two transistors in a so-called common source or common drain configuration. Numerous variations and permutations will be apparent to those skilled in the art with the benefit of the present teachings and routine experimentation.

Also shown in each of FIGS. 4c and 4d is an exemplary isolation region 47. One skilled in the art will recognize that isolation regions will be formed between the various illustrated features.

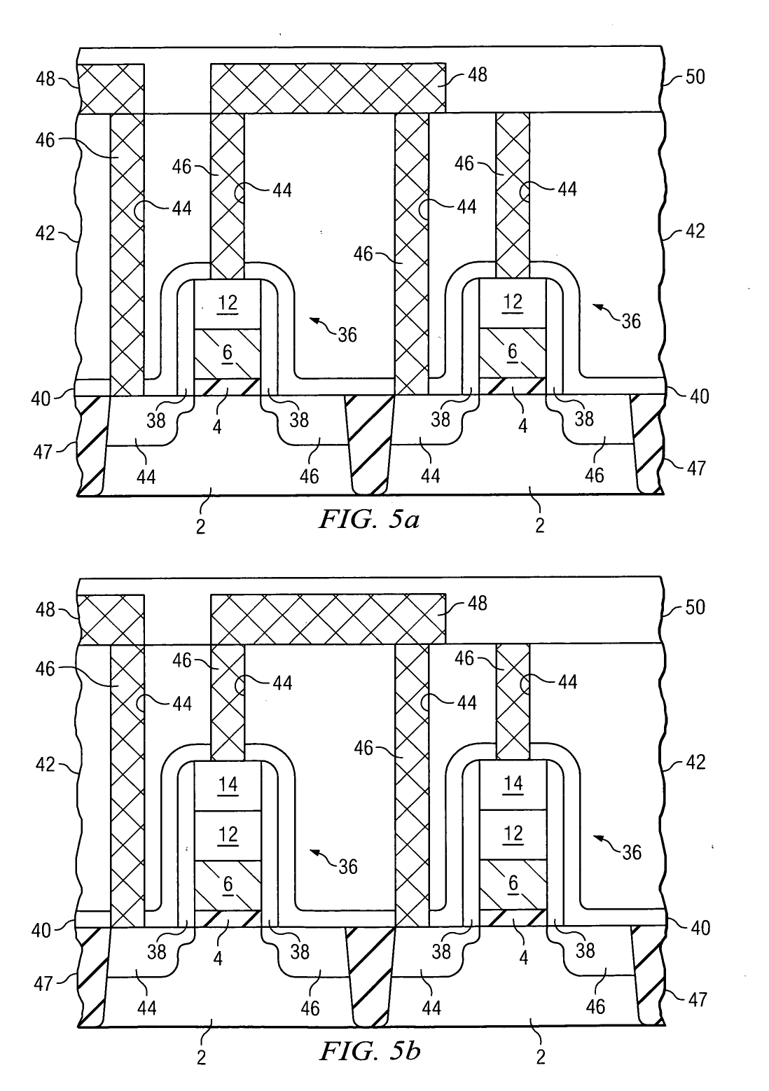

FIGS. 5a and 5b illustrate transistor devices including respective gate stacks 36 and respective source/drain regions 44, 46 after further processing. As shown, an etch stop layer (ESL) 40 is formed over the source/drain regions 44, 46 and the metal gate stacks 36. In the illustrative embodiment, ESL 40 comprises silicon nitride deposited using CVD or plasma enhanced chemical vapor deposition (PECVD), although other well-known materials could be employed. Inter-layer dielectric (ILD) 42 is formed atop ESL 40, again using well-known materials and deposition techniques. In one illustrative embodiment, ILD layer 42 is formed of SOG or HDPCVD oxide.

Contact openings 44 are formed through ILD 42 and ESL 40 using standard photolithographic and etch processes. The contact openings are filled with a conductor 46, such as doped polysilicon, tungsten, aluminum, titanium, tantalum, copper, gold, or the like. Finally metal interconnects 48 are formed over the transistor devices and ILD 42. These metal interconnects are preferably copper formed using a damascene or dual damascene process. Metal interconnects 48 interconnect the various transistors formed on the substrate along with other circuit components and, eventually connect the circuit to external signal and power lines. One skilled in the art will recognize that numerous layers of metal interconnects will be formed, one atop the other with intervening inter-metal dielectrics (IMDs) 50, with conventional vias interconnecting nodes of the respective stacked metal interconnect layers.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a substrate;
a substantially nitrogen-free interfacial layer on said substrate;
a nitrogen-containing high dielectric constant (high-k) layer directly on said interfacial layer; and
a metal electrode on said nitrogen-containing high-k layer.

2. The semiconductor device of claim 1 further comprising:
a first source/drain region formed in said substrate and substantially aligned with a first sidewall of said metal electrode; and
a second source/drain region formed in said substrate and substantially aligned with a second sidewall of said metal electrode.

3. The semiconductor device of claim 1 wherein said nitrogen-containing high-k layer is a metal oxide or a metal silicate containing at least one material selected from the group consisting of hafnium, aluminum, zirconium, lanthanum, tantalum, titanium, dysprosium, scandium, and combinations thereof.

4. The semiconductor device of claim 1 wherein said nitrogen-containing high-k layer comprises a material selected from the group consisting essentially of HfO2 and HfSiO, and has a silicon atomic ratio of between about ten percent and about ninety percent.

5. The semiconductor device of claim 1 wherein said nitrogen-containing high-k layer has a nitrogen atomic ration of between about five percent and about thirty percent.

6. The semiconductor device of claim 1 wherein said nitrogen-containing high-k layer has a thickness of between about 1 nm and about 10 nm and wherein said metal electrode has a thickness of between about 1 nm and about 30 nm.

7. The semiconductor device of claim 1 wherein said nitrogen-containing high-k layer is substantially amorphous.

8. The semiconductor device of claim 1 wherein said metal electrode is a gate electrode and wherein said gate electrode comprises a material selected from the group consisting essentially of tantalum, titanium, hafnium, ruthenium, molybdenum, tungsten, carbon, nitrogen, oxygen, and combinations thereof.

9. The semiconductor device of claim 1 wherein said interfacial layer comprises a material selected from the group consisting essentially of oxygen, nitrogen, silicon, hafnium, aluminum, zirconium, titanium, tantalum, lanthanum, dysprosium, scandium, and combinations thereof.

10. The semiconductor device of claim 1 further comprising:
a polysilicon electrode overlying said metal electrode.

11. The semiconductor device of claim 10 wherein said polysilicon electrode has a thickness of between about 30 nm and about 200 nm.

12. A semiconductor device comprising:
a semiconductor substrate;
a substantially nitrogen-free interfacial layer on said semiconductor substrate;
a gate dielectric on said interface layer, said gate dielectric comprising a nitrogen-containing material having a high dielectric constant;
a metal gate electrode on said gate dielectric;
a non-nitrogen-containing layer on said gate dielectric;
a first source/drain region in said substrate, wherein a portion of said first source/drain region underlies a first portion of said gate dielectric and gate electrode; and
a second source/drain region in said substrate, wherein a portion of said second source/drain region underlies a second portion of said gate dielectric and gate electrode.

13. The semiconductor device of claim 12 further comprising:
a contact formed in an opening in said non-nitrogen-containing layer and electrically coupling said metal gate electrode to another transistor formed on said substrate.

14. The semiconductor device of claim 12 wherein said interfacial layer comprises a material selected from the group consisting essentially of oxygen, nitrogen, silicon, hafnium, aluminum, zirconium, titanium, tantalum, dysprosium, scandium, and combinations thereof.

15. The semiconductor device of claim 12 wherein said gate dielectric comprises a material selected from the group consisting essentially of a metal oxide or a metal silicate containing at least one material selected from the group consisting of hafnium, aluminum, zirconium, lanthanum, tantalum, titanium, dysprosium, scandium, and combinations thereof.

16. The semiconductor device of claim 12 wherein said gate dielectric comprises a material selected from the group consisting essentially of HfO2 and HfSiO, and has a silicon atomic ratio of between about ten percent and about ninety percent.

17. The semiconductor device of claim 12 wherein said gate dielectric has a thickness of about 1 nm and about 10 nm and wherein said metal electrode has a thickness of between about 1 nm and about 30 nm.

18. The semiconductor device of claim 12 wherein said gate dielectric has a nitrogen atomic ration of between about five percent and about thirty percent.

19. An integrated circuit comprising:
a silicon substrate;
a transistor formed at least partially on said substrate, and including a source region;
a drain region;
a channel region defined between said source region and said drain region, said channel region having a nominal length of about or less than about 40 nm;
an interfacial layer overlying the channel region;
a nitrogen-containing high-k gate dielectric overlying the interfacial layer; and
a metal gate electrode overlying the gate dielectric;
an etch stop layer overlying the metal gate electrode;
an inter-layer dielectric over the etch stop layer;
a conductor in said etch stop layer and said inter-layer dielectric, said conductor substantially aligned with said gate electrode; and
an interconnect layer overlying the inter-layer dielectric and electrically contacting the conductor.

20. The integrated circuit of claim 19 wherein said substrate comprises silicon.

21. The integrated circuit of claim 19 wherein said gate dielectric comprises a material selected from the group consisting essentially of HfO2 and HfSiO.

22. The integrated circuit of claim 19 wherein said gate electrode comprises a material selected from the group consisting essentially of tantalum, titanium, hafnium, ruthenium, molybdenum, nitrogen, carbon, and combinations thereof.

23. The semiconductor device of claim 19 further comprising a polysilicon electrode overlying said metal electrode.

24. The semiconductor device of claim 19 wherein said nitrogen containing gate dielectric has a nitrogen atomic ratio of from about five percent to about thirty percent.
